(19) United States
(12) Patent Application Publication
(10) Pub. No.: US 2007/0241819 A1
(43) Pub. Date: Oct. 18, 2007

(54) Low-Offset, Wide Common Mode Range, Cascoded-Gain Single Stage Amplifier

(76) Inventors: Luthuli E. Dake, McKinney, TX (US); Rex M. Teggatz, Sachse, TX (US); Amer Hani Atrash, Dallas, TX (US)

Correspondence Address: TEXAS INSTRUMENTS INCORPORATED, P O BOX 655474, M/S 3999, DALLAS, TX, 75265, US

(21) Appl. No.: 11/694,067

(22) Filed: Mar. 30, 2007

Related U.S. Application Data
(60) Provisional application No. 60/787,354, filed on Mar. 30, 2006.

(51) Int. Cl. H03F 3/45

(52) U.S. Cl. 330/257

(57) ABSTRACT

The cascoded gain single stage amplifier includes: a common gate differential pair; a first amplifier having a first input coupled to a first leg of the differential pair, and a second input coupled to a second leg of the differential pair; a current mirror coupled to the differential pair; a second amplifier having a first input coupled to a first leg of the current mirror, and a second input coupled to a second leg of the current mirror.

### CLAIM OF PRIORITY

This application claims priority under 35 U.S.C. 119(e)(1) to U.S. Provisional Application No. 60/787,354 (TI-61492PS) filed Mar. 30, 2006.

### FIELD OF THE INVENTION

The present invention relates to electronic circuitry and, in particular, to a low-offset, cascoded gain single stage sense amplifier used in high voltage applications with wide common mode range (CMR).

### BACKGROUND OF THE INVENTION

Typical common gate differential pairs have an offset, especially those used as sense amps which require a wide common mode range (CMR). This offset is caused by the following two components. 1) The popularly known one is threshold voltage (V_{T}) mismatch, which is dependent on how effective matching techniques have on the technology process. 2) The usually over looked component is the effect even a small drain-to-source voltage (V_{ds}) mismatch has on the offset of the diff pair due to lambda issues. Table 1, below illustrates this numerically.

The source voltage of sense amp is given by;

$${V}_{S} = {V}_{G} + {V}_{T} + \sqrt{\frac{{I}_{D}}{K ( W \text{/} L ) ( 1 + λ {V}_{DS} )}}$$

Table 1, below uses the equation above to illustrate the effect of • on the input pair offset. The following assumptions are made; no V_{T} mismatch, I_{D} (drain current) is equal in both legs, and V_{G} (gate voltage) is equal.

From Table 1, it can be seen that when pushing for a very small offset, even a 100 mV V_{ds} mismatch on the input diff pair can cause a >1 mV input (Vₛ) offset if the process has a poor lambda. This tells us using a normal cascoded topology will not be adequate especially if the V_{ds} mismatch of the cascoded transistors is significant, which is expected in most sense amp applications.

TABLE 1

| Parameter | Example1 | Example2 | Example3 | Unit |
|---|---|---|---|---|
| I_{D} | 50 | 50 | 50 | uA |
| K(•Cox) | 1.3 | 1.3 | 1.3 | uA/V² |
| Lambda(•) | 0.04 | 0.004 | 0.04 | V⁻¹ |
| W/L | 10 | 10 | 10 | |
| Delta V_{DS} | 0.1 | 0.1 | 12 | V |
| Delta V_{S}(Offset) | 1.21 | 0.13 | 108.8 | mV |

A prior art single stage common gate sense amplifier is shown in FIG. 1. The prior art device of FIG. 1 includes low voltage (LV) PMOS transistors 20 and 22; low voltage (LV) NMOS transistors 26, 28, and 30; high voltage (HV) PMOS transistors 32 and 34; high voltage (HV) NMOS transistors 36, 38, and 40; current source 42; low voltage source LV Rail; input nodes IN and IP; and output voltage node Vo.

### SUMMARY OF THE INVENTION

A low-offset, wide CMR, cascoded gain single stage amplifier includes: a common gate differential pair; a first amplifier having a first input coupled to a first leg of the differential pair, and a second input coupled to a second leg of the differential pair; a current mirror coupled to the differential pair; a second amplifier having a first input coupled to a first leg of the current mirror, and a second input coupled to a second leg of the current mirror.

### BRIEF DESCRIPTION OF THE DRAWINGS

In the drawings:

FIG. 1 is a circuit diagram of a prior art single stage common gate sense amplifier;

FIG. 2 is a circuit diagram of a preferred embodiment low offset, wide CMR, cascoded gain single stage amplifier.

### DETAILED DESCRIPTION OF PREFERRED EMBODIMENTS

A preferred embodiment low offset, wide CMR, cascoded gain single stage sense amp is shown in FIG. 2. The device of FIG. 2 includes low voltage (LV) PMOS transistors 50 and 52; low voltage (LV) NMOS transistors 54, 56, 58, and 60; high voltage (HV) PMOS transistor 62; high voltage (HV) NMOS transistors 64 and 66; current source 68; low voltage source LV Rail; input nodes IN and IP; amplifiers Ah and Al; and output voltage node Vo. The preferred embodiment device of FIG. 2 produces a high gain, low offset, and wide common mode range in high voltage and wide voltage swing applications.

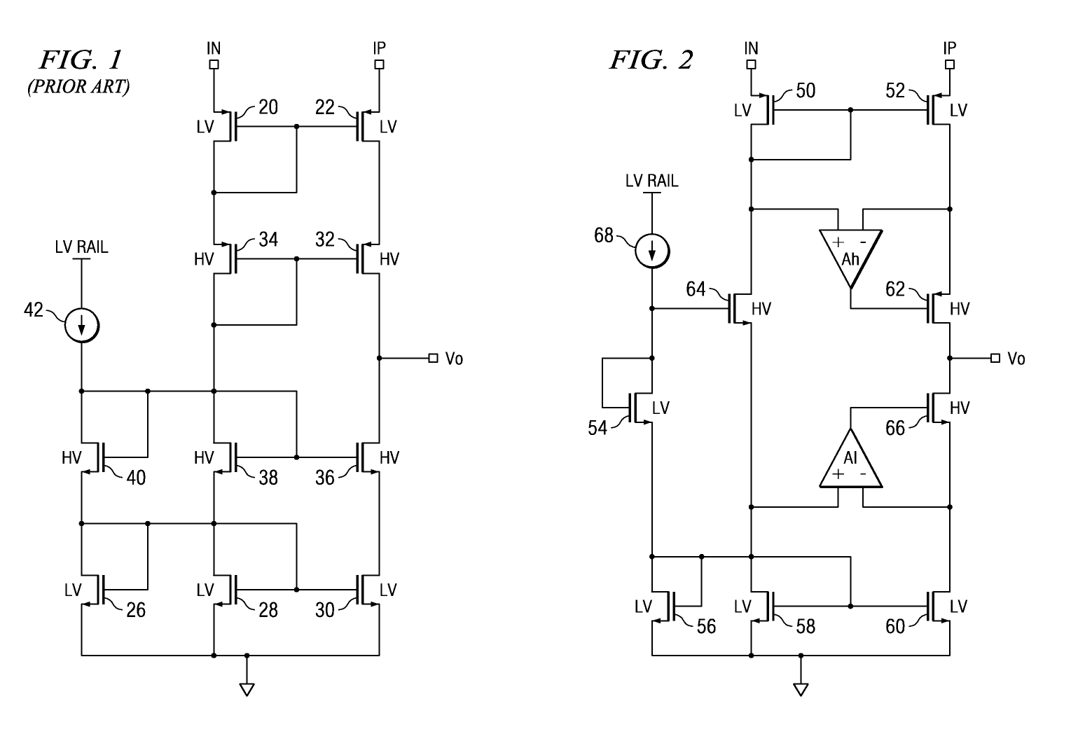

The preferred embodiment device of FIG. 1 uses a nested (or cascoded) gain architecture to achieve high gain in a single stage. The regulated current mirror technique used at input common gate differential pair (transistors 58 and 60), reduces offset due to Vds mismatch much more effectively than conventional cascade current mirror techniques. The regulated current mirror technique used at input common gate differential pair (transistors 58 and 60), also provides a wide CMR much more effectively than conventional cascade current mirror techniques. Nested amps Ah and Al help reduce the Vds mismatch. Transistors 50 and 50 form a current mirror. Since the preferred embodiment topology uses only one gain stage, it is easier to stabilize. The common mode range lower limit is 2(Vt+Vds) and the upper limit is as high as the process can accommodate.

A single stage gain of up to 140 dB can be obtained based on the well known gain boost technique in the preferred embodiment of FIG. 2. From the analysis below, the total gain is basically, cascoded amp gain (typically 60 dB-80 dB) multiplied by the gain of the nested amp (typically 40 dB-60 dB). This is equivalent to having a two stage amplifier without the problems of the extra pole.

Output resistance of a conventional prior art cascoded current mirror shown in FIG. 1 is:

$${R}_{o} = \frac{{g}_{m 2}}{{g}_{o 1} {g}_{o 2}}$$

Where gₘ₂ is the transconductance of transistor 32, gₒ₁ is the inverted output impedance of transistor 22, and gₒ₂ is the inverted output impedance of transistor 32.

However, output resistance of the preferred embodiment regulated cascode current mirror shown in FIG. 2 is:

$${R}_{o} = A \frac{{g}_{m 2}}{{g}_{o 1} {g}_{o 2}}$$

If A_{L}=A_{H}=A, is open loop gain of nested amps Al and Ah.

Where gₘ₂ is the transconductance of transistor 62, gₒ₁ is the inverted output impedance of transistor 52, and gₒ₂ is the inverted output impedance of transistor 62.

Therefore the gain of the preferred embodiment sense amp is:

$${A}_{sen} = {g}_{m\_in} {R}_{o} = A \frac{{g}_{m\_in} {g}_{m 2}}{{g}_{o 1} {g}_{o 2}}$$

Where gₘ_{_{—}}ᵢₙ, is the transconductance of transistor 52 or 50.

From above equation it is clear that the preferred embodiment topology of FIG. 2 multiplies the gain by A without the need of another stage and concomitant stability issues.

While this invention has been described with reference to an illustrative embodiment, this description is not intended to be construed in a limiting sense. Various modifications and combinations of the illustrative embodiment, as well as other embodiments of the invention, will be apparent to persons skilled in the art upon reference to the description. It is therefore intended that the appended claims encompass any such modifications or embodiments.

What is claimed is:

1. A cascoded gain single stage amplifier comprising:
a common gate differential pair;
a first amplifier having a first input coupled to a first leg of the differential pair, and a second input coupled to a second leg of the differential pair;
a current mirror coupled to the differential pair;
a second amplifier having a first input coupled to a first leg of the current mirror, and a second input coupled to a second leg of the current mirror.

2. The device of claim 1 further comprising:
a first transistor coupled between the second leg of the differential pair and an output node; and
a second transistor coupled between the second leg of the current mirror and the output node.

3. The device of claim 2 wherein a control node of the first transistor is controlled by the first amplifier.

4. The device of claim 2 wherein a control node of the second transistor is controlled by the second amplifier.

5. The device of claim 1 further comprising a transistor coupled between the first leg of the differential pair and the first leg of the current mirror.

6. The device of claim 2 further comprising a third transistor coupled between the first leg of the differential pair and the first leg of the current mirror.

7. The device of claim 1 further comprising a bias source coupled to a control node of the differential pair.

8. The device of claim 5 further comprising a bias source having a first output coupled to a control node of the differential pair, and a second output coupled to a control node of the transistor.

9. The device of claim 8 wherein the bias source comprises:
a current source;
a first bias source transistor coupled to the current source and coupled to the control node of the transistor; and
a second bias source transistor coupled to the first bias source transistor and coupled to the control node of the differential pair.
